(19) United States
(12) Patent Application Publication
(10) Pub. No.: US 2026/0247711 A1
(43) Pub. Date: Aug. 20, 2026

(54) DISPLAY SUBSTRATE AND DISPLAY DEVICE

(71) Applicants: BOE MLED Technology Co., Ltd., Beijing (CN); BOE TECHNOLOGY GROUP CO., LTD., Beijing (CN)

(72) Inventors: Zeng LIANG, Beijing (CN); Yicheng LIN, Beijing (CN); Qiuhua MENG, Beijing (CN); Huanxin YUE, Beijing (CN); Linfeng LI, Beijing (CN); Qingkai ZHANG, Beijing (CN); Sen YAN, Beijing (CN)

(21) Appl. No.: 18/832,882

(22) PCT Filed: Jul. 31, 2023
(86) PCT No.: PCT/CN2023/110188

§ 371 Date: Jul. 24, 2024

(51) Int. Cl. H10D 86/40

(52) U.S. Cl. CPC H10D 86/441; H10D 86/451

(57) ABSTRACT

The present disclosure provides a display substrate and a display device. The display substrate includes: a base substrate and a plurality of pixel driving circuits on the base substrate. The display substrate further includes a first level signal input layer and an electro-static discharge layer. At least part of the electro-static discharge layer is at a side of the pixel driving circuit facing the base substrate. The electro-static discharge layer is coupled to the first level signal input layer.

### TECHNICAL FIELD

The present disclosure relates to the field of display technology, in particular to a display substrate and a display device.

### BACKGROUND

With the continuous development of display technology, application fields of display products are becoming more and more extensive, and requirements of people for the quality and pass rate of display products are also increasing.

In the actual production of the display product, static electricity is generated during the process of side, bonding, die bonding, film tearing, etc. In order to prevent circuit damage caused by excessive static electricity accumulated inside the display product, an electro-static discharge (ESD) structure including a circuit structure is arranged inside the display product in related technologies.

### SUMMARY

An object of the embodiments of the present disclosure is to provide a display substrate and a display device.

In order to achieve the above object, the present disclosure provides the following technical solutions.

According to the first aspect of the present disclosure, a display substrate is provided and includes:
a base substrate and a plurality of pixel driving circuits arranged on the base substrate; the display substrate further including a first level signal input layer and an electro-static discharge layer, where at least part of the electro-static discharge layer is arranged on a side of the pixel driving circuit facing the base substrate, and the electro-static discharge layer is coupled to the first level signal input layer.

Optionally, the first level signal input layer includes a power layer, and the electro-static discharge layer is coupled to the power layer.

Optionally, the first level signal input layer includes a cathode layer, and the electro-static discharge layer is coupled to the cathode layer.

Optionally, the first level signal input layer includes a light shielding layer, where at least part of the light shielding layer is arranged between the pixel driving circuit layer and the base substrate, and the pixel driving circuit includes a plurality of transistors, where the transistors include an active layer, the orthotropic projection of the light shielding layer on the base substrate overlaps at least partially with the orthotropic projection of the active layer included in at least part of the transistor on the base substrate; and the electro-static discharge layer is coupled to the light shielding layer.

Optionally, at least part of the electro-static discharge layer is arranged between the light shielding layer and the base substrate, and the electro-static discharge layer is coupled to the light shielding layer through a via-hole; or, the electro-static discharge layer is arranged with the light shielding layer on the same layer, and the electro-static discharge layer is directly overlapped with the light shielding layer.

Optionally, the overlapping region between the orthographic projection of the electro-static discharge layer on the base substrate and the orthographic projection of the light shielding layer on the base substrate is less than or equal to 10% of the region of the electro-static discharge layer.

Optionally, the display substrate further includes a light shielding layer, where at least part of the light shielding layer is arranged between the pixel driving circuit layer and the base substrate; and the orthotropic projection of the electro-static discharge layer on the base substrate does not overlap with the orthotropic projection of the light shielding layer on the base substrate.

Optionally, the display substrate includes a power layer and a cathode layer; the power layer includes a plurality of power lines arranged along a first direction, where the power lines include at least a portion extending along a second direction, and the first direction intersects with the second direction; and the cathode layer includes a plurality of cathode lines arranged along the first direction, and the cathode lines include at least a portion extending along the second direction; and
the electro-static discharge layer is formed into a grid shape, and the electro-static discharge layer includes a plurality of a first grid portion extending along the first direction and a plurality of a second grid portion extending along the second direction; the orthographic projection of at least one second grid portion on the base substrate overlaps at least partially with the orthographic projection of the power line on the base substrate; and/or, the orthogonal projection of at least one second grid portion on the base substrate overlaps at least partially with the orthogonal projection of the cathode line on the base substrate.

Optionally, the display substrate includes a plurality of a clock signal lines arranged along a second direction, where the clock signal lines includes at least a portion extending along the first direction, and the pixel driving circuit coupled to the corresponding clock signal lines; and the orthographic projection of the first grid portion on the base substrate overlaps at least partially with the orthographic projection of the clock signal line on the base substrate.

Optionally, the electro-static discharge layer includes a plurality of a first openings, and the orthogonal projection of the boundary of the first opening on the base substrate includes a curved edge portion; and the orthographic projection of the first opening on the base substrate overlaps at least partially with the orthographic projection of the pixel driving circuit on the base substrate.

Optionally, the electro-static discharge layer includes a plurality of a second openings, and the orthogonal projection of the boundary of the second opening on the base substrate includes a straight edge portion; and the orthographic projection of the second opening on the base substrate does not overlap with the orthographic projection of the pixel driving circuit on the base substrate.

Optionally, the orthogonal projection of the boundary of the second opening on the base substrate includes at least one serrated portion.

Optionally, the pixel driving circuit includes a driving transistor and a storage capacitor, a first electrode plate of the storage capacitor is coupled to a gate of the driving transistor, and a second electrode plate of the storage capacitor is coupled to the power layer; and
the orthographic projection of the second electrode plate on the base substrate has an overlapping region with the orthographic projection of the electro-static discharge layer on the base substrate, and the second electrode plate is coupled to the electro-static discharge layer through a via-hole in the overlapping region.

Optionally, the display substrate further includes a first conductive connection portion, the first conductive connection portion is coupled to the power line, and at least part of the first conductive connection portion is arranged on a side of the power line away from the base substrate; and
the orthographic projection of the first conductive connection portion on the base substrate has an overlapping region with the orthographic projection of the electro-static discharge layer on the base substrate, and the first conductive connection portion is coupled to the electro-static discharge layer through a via-hole.

Optionally, the display substrate further includes a first conductive connection portion and a second conductive connection portion, where at least part of the second conductive connection portion is arranged on a side of the first conductive connection portion away from the base substrate; the first conductive connection portion is coupled to the second conductive connection portion and the power layer respectively; and the orthographic projection of the second conductive connection portion on the base substrate has an overlapping region with the orthographic projection of the electro-static discharge layer on the base substrate, and the second conductive connection portion is coupled to the electro-static discharge layer through a via-hole.

Optionally, the display substrate further includes a third conductive connection portion, where the third conductive connection portion is coupled to the cathode layer, and at least part of the third conductive connection portion is arranged on a side of the cathode layer away from the base substrate; and
the orthographic projection of the third conductive connection portion on the base substrate has an overlapping region with the orthographic projection of the electro-static discharge layer on the base substrate, and the third conductive connection portion is coupled to the electro-static discharge layer through a via-hole.

Optionally, the display substrate further includes a first connection electrode and a third conductive connection portion, where at least part of the first connection electrode is arranged on a side of the third conductive connection portion away from the base substrate; the third conductive connection portion is coupled to the first connection electrode and the cathode layer respectively; and the orthographic projection of the first connection electrode on the base substrate has an overlapping region with the orthographic projection of the electro-static discharge layer on the base substrate, and the first connection electrode is coupled to the electro-static discharge layer through a via-hole in the overlapping region.

Optionally, the orthographic projection of the cathode layer on the base substrate has an overlapping region with the orthographic projection of the electro-static discharge layer on the base substrate, and the cathode layer is coupled to the electro-static discharge layer through a via-hole in the overlapping region.

Optionally, the electro-static discharge layer is made of indium tin oxide material or amorphous silicon.

Based on the technical solution of the display substrate mentioned above, the second aspect of the disclosure provides a display device, including the display substrate mentioned above.

### BRIEF DESCRIPTION OF THE DRAWINGS

The accompanying drawings, which are included to provide a further understanding of the present disclosure, constitute a part of the present disclosure. Illustrative embodiments of the present disclosure and the description are used to explain the present disclosure and do not constitute undue limitation to the disclosure. In the drawings:

FIG. 1 is a circuit schematic diagram of a pixel driving circuit provided in the embodiment of the present disclosure;

FIG. 2 is a schematic diagram showing layout of an electro-static discharge layer provided in the embodiment of the present disclosure;

FIG. 3 is a schematic diagram showing a layout position relationship between an electro-static discharge layer and a pixel driving circuit layout area provided in the embodiment of the present disclosure;

FIG. 4 is a schematic diagram showing layout of the electro-static discharge layer shown in FIG. 3;

FIG. 5 is a schematic diagram showing layout of a light shielding layer shown in FIG. 3;

FIG. 6 is a schematic diagram showing layout of a conductive layer shown in FIG. 3;

FIG. 7 is a schematic diagram showing a first layout of an electro-static discharge layer provided in the embodiment of the present disclosure;

FIG. 8 is a schematic diagram showing a second layout of an electro-static discharge layer provided in the embodiment of the present disclosure;

FIG. 9 is a schematic diagram showing a third layout of an electro-static discharge layer provided in the embodiment of the present disclosure;

FIG. 10 is a schematic diagram showing a fourth layout of an electro-static discharge layer provided in the embodiment of the present disclosure;

FIG. 11 is a schematic diagram showing a fifth layout of an electro-static discharge layer provided in the embodiment of the present disclosure;

FIG. 12 is a schematic diagram showing a sixth layout of an electro-static discharge layer provided in the embodiment of the present disclosure;

FIG. 13 is a schematic diagram showing a first layout of two adjacent pixel driving circuits in a display substrate provided in the embodiment of the present disclosure;

FIG. 14 is a schematic diagram showing layout of structures after removing a conductive layer shown in FIG. 13;

FIG. 15 is an enlarged schematic diagram of a part A1 in FIG. 14;

FIG. 16 is a schematic diagram showing layout of an electro-static discharge layer and a light shielding layer in FIG. 14;

FIG. 17 is a first cross-sectional schematic diagram of a display substrate provided in the embodiment of the present disclosure;

FIG. 18 is a flow chart of a manufacturing process of a structure in which a second electrode plate is coupled to a light shielding layer provided in the embodiment of the present disclosure;

FIG. 19 is a schematic diagram showing a second layout of two adjacent pixel driving circuits in a display substrate provided in the embodiment of the present disclosure;

FIG. 20 is an enlarged schematic diagram of a part in FIG. 19 at the same position as the part A1 of FIG. 13;

FIG. 21 is a second cross-sectional schematic diagram of a display substrate provided in the embodiment of the present disclosure;

FIG. 22 is a third cross-sectional schematic diagram of a display substrate provided in the embodiment of the present disclosure;

FIG. 23 is a fourth cross-sectional schematic diagram of a display substrate provided in the embodiment of the present disclosure;

FIG. 24 is a flow chart of a manufacturing process of a structure in which a cathode layer is coupled to a light shielding layer provided in the embodiment of the present disclosure;

FIG. 25 is a schematic diagram showing a first layout of three adjacent pixel driving circuits in a display substrate provided in the embodiment of the present disclosure;

FIG. 26 is a schematic diagram showing layout of the light shielding layer shown in FIG. 25;

FIG. 27 is a fifth cross-sectional schematic diagram of a display substrate provided in the embodiment of the present disclosure;

FIG. 28 is a flow chart of a manufacturing process of a structure in which a second conductive connection portion is coupled to a light shielding layer provided in the embodiment of the present disclosure;

FIG. 29 is a schematic diagram showing a second layout of three adjacent pixel driving circuits in a display substrate provided in the embodiment of the present disclosure; and

FIG. 30 is a sixth cross-sectional schematic diagram of a display substrate provided in the embodiment of the present disclosure.

### DETAILED DESCRIPTION

In order to further explain the display substrate and the display device provided by the embodiments of the present disclosure, a detailed description will be given below with reference to the accompanying drawings.

In order to prevent circuit damage caused by excessive static electricity accumulated inside the display product, an ESD structure including the circuit structure is arranged inside the display product in the related art. However, the ESD structure is difficult to completely prevent electro-static damage caused by ESD during die bonding, etc.

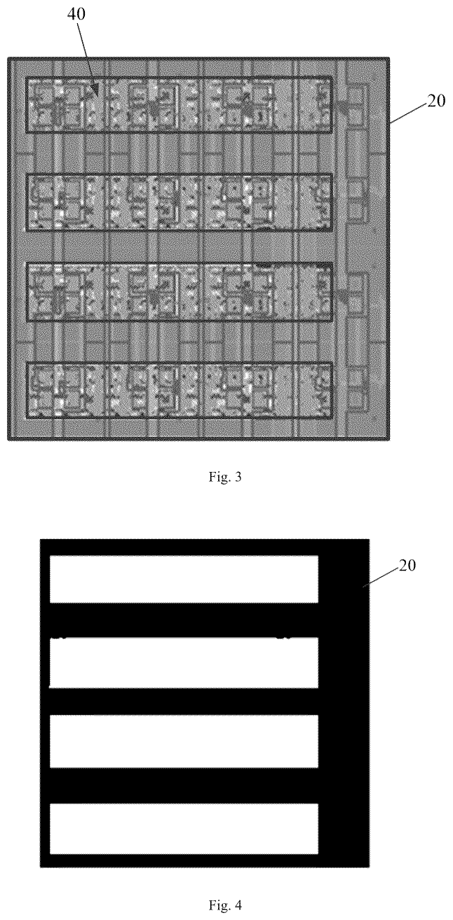

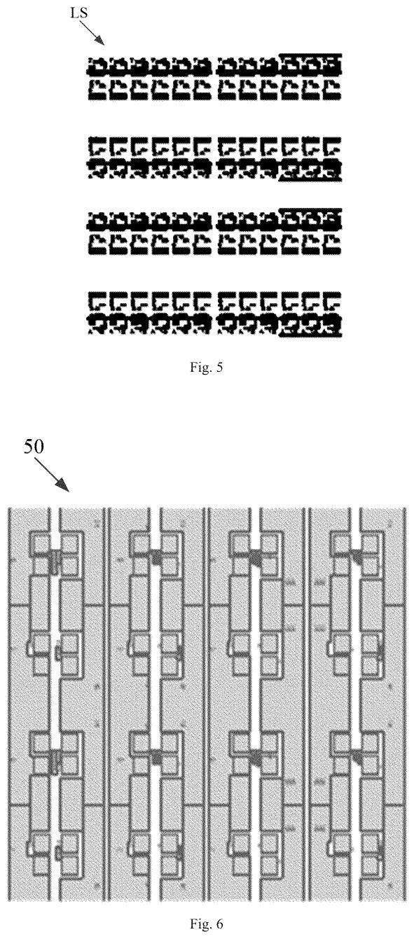

Refer to FIGS. 2 to 6 and FIG. 17, the embodiment of the present disclosure provides a display substrate, including: a base substrate 10 and a plurality of pixel driving circuits arranged on the base substrate 10 (for example, arranged on a layout region 40 as shown in FIG. 3, including a transistor structure TFT); and the display substrate further includes a first level signal input layer (for example, including a power layer VDD) and an electro-static discharge layer 20, at least part of the electro-static discharge layer 20 is arranged on a side of the pixel driving circuit facing the base substrate 10, and the electro-static discharge layer 20 is coupled to the first level signal input layer.

It should be noted that FIG. 2 further shows the shift register unit GOA included in the display substrate, the red light-emitting element R corresponds to the position of the coupled pixel driving circuit, the green light-emitting element G corresponds to the position of the coupled pixel driving circuit, and the blue light-emitting element B corresponds to the position of the coupled pixel driving circuit.

For example, the plurality of pixel driving circuits are distributed on the base substrate 10 in an array. The plurality of pixel driving circuits are divided into a plurality of rows of pixel driving circuits and a plurality of columns of pixel driving circuits. The plurality of rows of pixel driving circuits are arranged along a first direction, and each row of pixel driving circuits includes a plurality of pixel driving circuits arranged along a second direction. The plurality of columns pixel driving circuits are arranged along the second direction, and each column of pixel driving circuits includes a plurality of pixel driving circuits arranged along the first direction. For example, the first direction intersects with the second direction. For example, the first direction includes a longitudinal direction, and the second direction includes a transverse direction.

For example, the display substrate further includes a cathode layer VSS, the cathode layer VSS can be used for transmitting negative power signals, but is not limited to this. The display substrate further includes a plurality of light-emitting elements, and the types of light-emitting elements are diverse. For example, each light-emitting element includes three light-emitting units, and the three light-emitting units can be selected as red light-emitting units, green light-emitting units, and blue light-emitting units. The light-emitting element includes one first pin and three second pins, where the first pin is coupled to the cathode layer VSS, the three second pins correspond to the three light-emitting units one by one, and the second pin is coupled to the corresponding pixel driving circuit to receive the driving signal provided by the pixel driving circuit. Each light-emitting unit can achieve independent control of light emission under the driving of the corresponding pixel driving circuit. For example, each light-emitting element includes one light-emitting unit, the one light-emitting unit includes a red light-emitting unit, a green light-emitting unit, or a blue light-emitting unit, and the light-emitting element includes one first pin and one second pin, where the first pin is coupled to the cathode layer VSS, and the second pin is coupled to the corresponding pixel driving circuit to receive the driving signal provided by the pixel driving circuit. The light-emitting unit can achieve independent control of light emission under the driving of the corresponding pixel driving circuit.

For example, the display substrate further includes a first level signal input layer, where the first level signal input layer is used for transmitting a first level signal with a stable potential.

For example, the display substrate further includes an electro-static discharge layer 20, where the electro-static discharge layer is made of high resistance materials such as indium tin oxide (ITO) or amorphous silicon material, but is not limited to this. At least part of the electro-static discharge layer 20 is arranged on a side of the pixel driving circuit facing the base substrate 10. The electro-static discharge layer 20 can be directly or indirectly coupled to the first level signal input layer.

For example, an ITO conductive film layer is plated on the base substrate 10. The thickness of the film layer is between 40 nm and 100 nm, which may include endpoint values. The ITO conductive film layer is subjected to a patterning process to form the electro-static discharge film layer.

According to the specific structure of the display substrate, the display substrate provided in the embodiment of the disclosure includes a first level signal input layer and an electro-static discharge layer 20, at least part of the electro-static discharge layer 20 is arranged on a side of the pixel driving circuit facing the base substrate 10, and the electro-static discharge layer 20 is coupled to the first level signal input layer. The arrangement makes the electro-static discharge layer 20 have the same stable first level signal as the first level signal input layer. The electro-static discharge layer 20 can discharge the static electricity generated in the process of manufacturing the display substrate in time, which effectively preventing the ESD damage generated in the stages such as side, binding, and die bonding, playing the function of electro-static protection, and improving the product yield.

Moreover, in the display substrate provided in the embodiment of the disclosure, the electro-static discharge layer 20 is arranged on a side of the pixel driving circuit facing the base substrate 10. The arrangement is conducive to shortening the distance between the light-emitting element and the corresponding pixel driving circuit, which can effectively reduce the difficulty of manufacturing the display substrate. At the same time, the electro-static discharge layer 20 can be manufactured in the Array process used for manufacturing display substrate, and there is no need to add a separate process to manufacture the electro-static discharge layer 20 after completing the Array process. Therefore, the display substrate provided in the embodiment of the disclosure has lower manufacturing difficulty and simple manufacturing process flow, and is conducive to reducing the production cost of the display substrate.

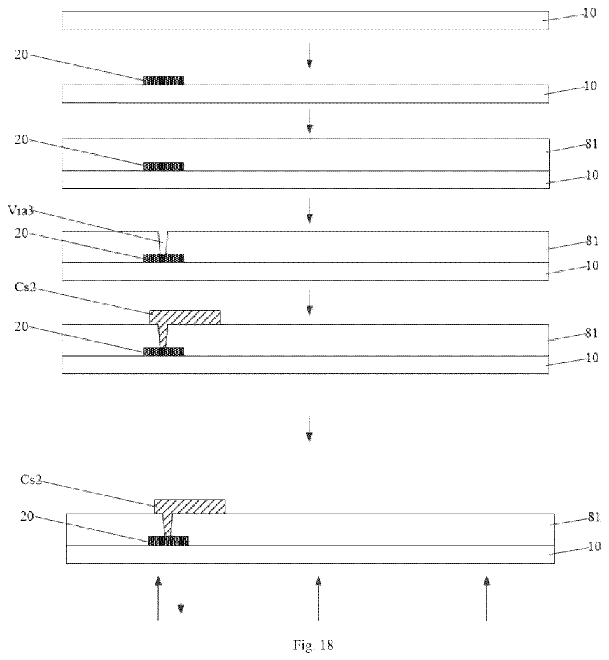

In addition, in the display substrate provided in the embodiment of the disclosure, the electro-static discharge layer 20 is arranged on a side of the pixel driving circuit facing the base substrate 10, so that the electro-static discharge layer 20 can enhance the protective effect against the laser. When the display substrate is in backside laser etching, the electro-static discharge layer 20 can reflect part of the laser energy, which can reduce the damage to the transistors of the pixel driving circuit on the front side. Refer to the last subfigure in FIG. 18, which illustrates the reflection of the laser.

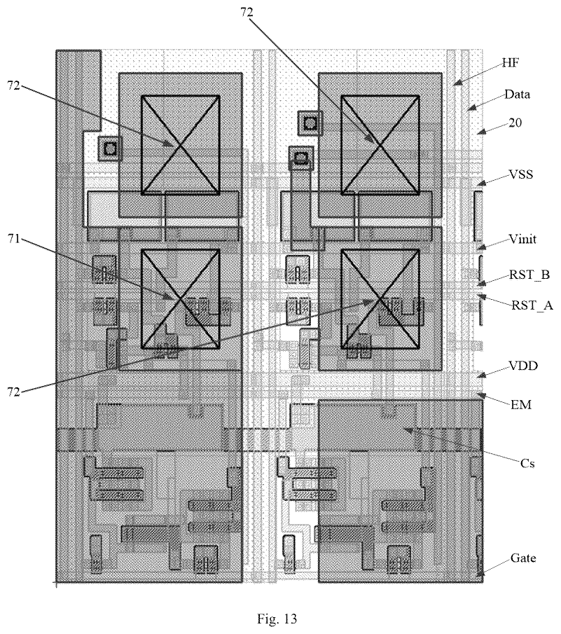

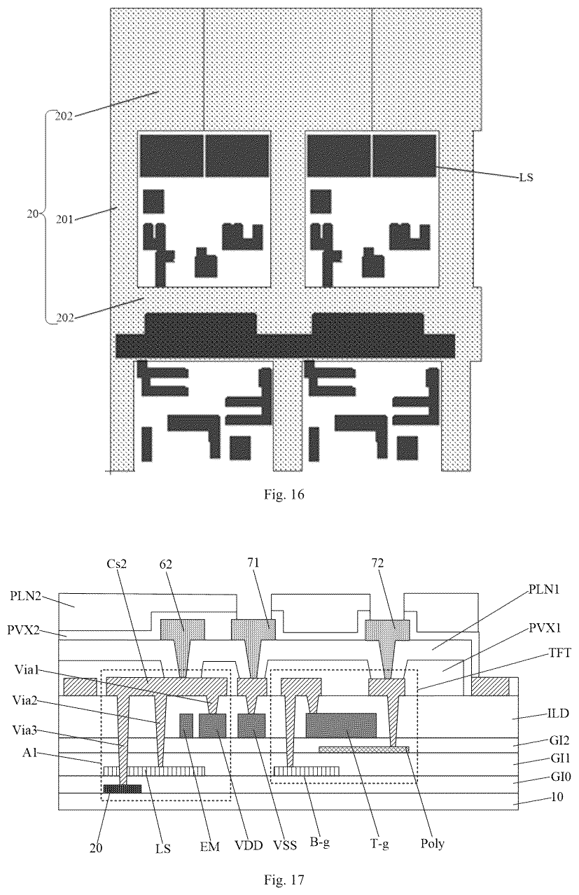

As shown in FIGS. 13 to 18, in some embodiments, the first level signal input layer includes a power layer VDD, and the electro-static discharge layer 20 is coupled to the power layer VDD.

It should be noted that the cross-sectional diagram along the B1B2 direction in FIG. 15 is shown as the part A1 of FIG. 17. An insulation layer 81 in FIG. 18 includes an insulation layer GI0, a first insulation layer GI1, a second insulation layer GI2 and an interlayer insulation layer ILD.

For example, the power layer VDD is used for transmitting power signals, and the power signals have a stable potential.

As shown in FIG. 17, for example, the display substrate includes a light shielding layer LS, a first insulation layer GI1, an active layer Poly, a second insulation layer GI2, a gate metal layer (e.g. top gate T-g including transistor structure TFT), an interlayer insulation layer ILD, a source drain metal layer, a first passivation layer PVX1, a first planarization layer PLN1, a conductive layer 50, a second passivation layer PVX2, and a second planarization layer PLN2, which are sequentially stacked along a direction away from the base substrate 10.

For example, the power layer VDD is arranged with the same layer and the same material as the gate metal layer, but is not limited to this.

For example, the first insulation layer, the active layer, the second insulation layer, the gate metal layer, the interlayer insulation layer, and the source drain metal layer are used for forming the pixel driving circuit.

In the display substrate provided in the above embodiment, the first level signal input layer includes a power layer VDD, the electro-static discharge layer 20 is coupled to the power layer VDD, and the existing power layer VDD for transmitting a stable signal can be multiplexed as a first level signal transmission layer, avoiding adding an additional patterning process, thereby simplifying the structure and manufacturing process flow of the display substrate and reducing the production cost of the display substrate. In addition, the above arrangement is conducive to reducing the IR Drop of the VDD at the power layer and improving the display uniformity of the display substrate.

The arrangement makes the electro-static discharge layer 20 have the same stable power signal as the power layer VDD, and the electro-static discharge layer 20 can discharge the static electricity generated in the process of manufacturing the display substrate in time, which effectively preventing the ESD damage produced in the stages such as side, binding, and die bonding, playing the function of electro-static protection, and improving the product yield.

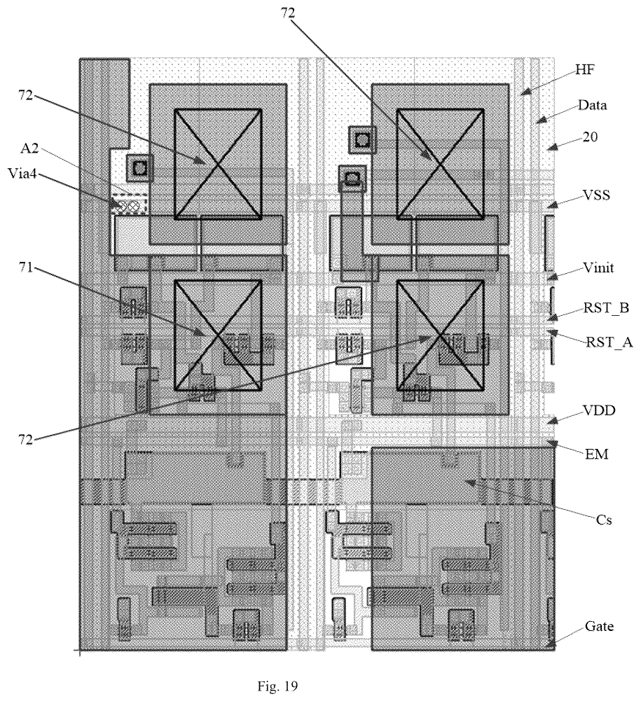

As shown in FIG. 19 to FIG. 24, in some embodiments, the first level signal input layer includes a cathode layer VSS, and the electro-static discharge layer 20 is coupled to the cathode layer VSS.

For example, the cathode layer VSS is used to transmit a negative power signal, and the negative power signal has a stable potential.

For example, the cathode layer VSS is arranged with the same layer and the same material as the gate metal layer, but is not limited to this.

In the display substrate provided in the embodiment, the first level signal input layer includes a cathode layer VSS, the electro-static discharge layer 20 is coupled to the cathode layer VSS, and the existing cathode layer VSS for transmitting a stable signal can be used to multiplex as a first level signal transmission layer, avoiding adding an additional patterning process, thereby simplifying the structure and manufacturing process flow of the display substrate and reducing the production cost of the display substrate. In addition, the above arrangement is conducive to reducing the IR Drop of the VSS of the cathode layer and improving the display uniformity of the display substrate.

The arrangement makes the electro-static discharge layer 20 have the same stable signal as the cathode layer VSS, and the electro-static discharge layer 20 can discharge the static electricity generated in the process of manufacturing the display substrate in time, which effectively preventing the ESD damage generated in the stages such as side, binding, and die bonding, playing the function of electro-static protection, and improving the product yield.

In some embodiments, the first level signal input layer includes a light shielding layer LS, at least part of the light shielding layer LS is arranged between the pixel driving circuit layer and the base substrate 10, the pixel driving circuit includes a plurality of transistors, the transistor includes an active layer, and the orthotropic projection of the light shielding layer LS on the base substrate 10 overlaps at least partially with the orthotropic projection of the active layer included in at least some transistors on the base substrate 10; and the electro-static discharge layer 20 is coupled to the light shielding layer LS.

As shown in FIG. 17, the light shielding layer LS can be used to form the bottom gate B-g of the transistor structure TFT, but is not limited to this.

For example, the light shielding layer LS includes a plurality of first light shielding patterns and a plurality of second light shielding patterns, where the first light shielding pattern is coupled to the power layer VDD, so that the first light shielding pattern has a stable power signal. The orthotropic projection of the second light shielding pattern on the base substrate 10 overlaps with the orthotropic projection of the channel portion of the active layer Poly on the base substrate 10. The channel portion of the transistor is obscured by the second light shielding pattern, which is conducive to ensuring the stability of the characteristics of the transistor.

For example, the second light shielding pattern is multiplexed as the bottom gate of the transistor it obscured, and the bottom gate of the transistor is coupled to the top gate, but is not limited to this.

For example, the electro-static discharge layer 20 is arranged in a different layer from the light shielding layer LS, at least part of the electro-static discharge layer 20 is arranged between the light shielding layer LS and the base substrate 10, and electro-static discharge layer 20 is coupled to the light shielding layer LS through a via-hole; or, the electro-static discharge layer 20 is arranged with the same layer as the light shielding layer LS, and the electro-static discharge layer 20 is directly overlapped with the light shielding layer LS.

For example, the overlapping area between the orthotropic projection of the electro-static discharge layer 20 on the base substrate 10 and the orthotropic projection of the light shielding layer LS on the base substrate 10 is less than or equal to 20% of the area of the electro-static discharge layer 20.

For example, the overlapping area between the orthotropic projection of the electro-static discharge layer 20 on the base substrate 10 and the orthotropic projection of the light shielding layer LS on the base substrate 10 is less than or equal to 10% of the area of the electro-static discharge layer 20.

For example, the overlapping area between the orthotropic projection of the electro-static discharge layer 20 on the base substrate 10 and the orthotropic projection of the light shielding layer LS on the base substrate 10 is less than or equal to 5% of the area of the electro-static discharge layer 20.

In the display substrate provided in the above embodiment, the first level signal input layer includes a light shielding layer LS, and the electro-static discharge layer 20 is coupled to the light shielding layer LS, and the existing cathode layer VSS for transmitting a stable signal can be used to multiplex as a first level signal transmission layer, avoiding adding an additional patterning process, thereby simplifying the structure and manufacturing process flow of the display substrate and reducing the production cost of the display substrate. In addition, the above arrangement is conducive to reducing the IR Drop of the power layer VDD and improving the display uniformity of the display substrate.

The above arrangement makes the electro-static discharge layer 20 have the same stable signal as the light shielding layer LS, and the electro-static discharge layer 20 can discharge the static electricity generated in the process of manufacturing the display substrate in time, which effectively preventing the ESD damage generated in the stages such as side, binding, and die bonding, playing the function of electro-static protection, and improving the product yield.

The above arrangement ensures that the electro-static discharge layer 20 is coupled to the light shielding layer LS and at the same time minimizes the overlapping area between the orthotropic projection of the electro-static discharge layer 20 on the base substrate 10 and the orthotropic projection of the light shielding layer LS on the base substrate 10, which can make the electro-static discharge layer 20 avoid the light shielding layer LS in a large area, avoiding damage to the film formation of the light shielding layer LS due to the presence of the electro-static discharge layer 20.

As shown in FIGS. 3 to 5, in some embodiments, the display substrate further includes a light shielding layer LS, where at least part of the light shielding layer LS is arranged between the pixel driving circuit layer and the base substrate 10; and the orthotropic projection of the electro-static discharge layer 20 on the base substrate 10 does not overlap with the orthotropic projection of the light shielding layer LS on the base substrate 10.

The above arrangement enables the electro-static discharge layer 20 to completely avoid the light shielding layer LS, avoiding damage to the film formation of the light shielding layer LS due to the presence of the electro-static discharge layer 20.

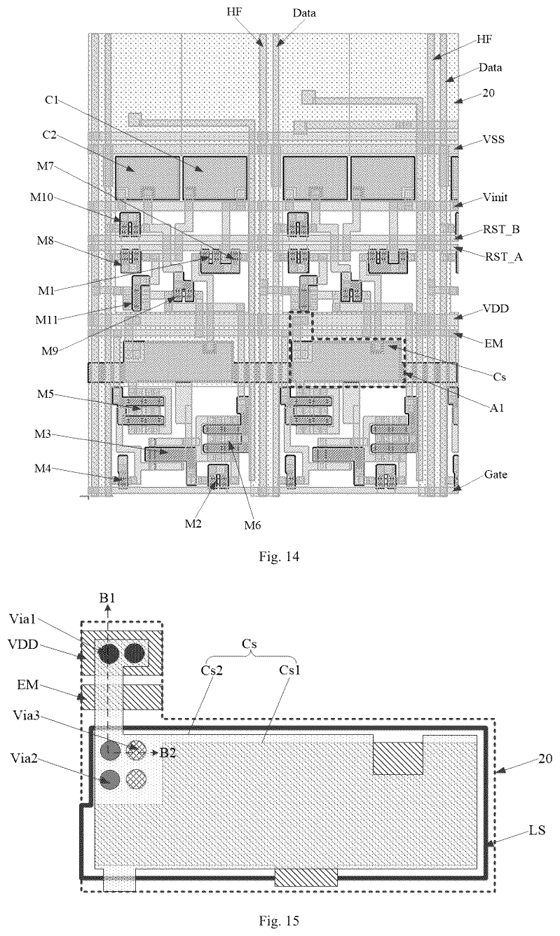

As shown in FIGS. 13, 14, and 16, in some embodiments, the display substrate include a power layer VDD and a cathode layer VSS; the power layer VDD includes a plurality of power lines arranged along a first direction (one power line is illustrated in FIG. 14), the power lines include at least a portion extending along a second direction, and the first direction intersects with the second direction; and the cathode layer VSS includes a plurality of cathode lines arranged along a first direction (one cathode line is illustrated in FIG. 14), and the cathode line includes at least a portion extending along the second direction; and
the electro-static discharge layer 20 is formed into a grid shape, the electro-static discharge layer 20 includes a plurality of first grid portions 201 extending along the first direction and a plurality of second grid portions 202 extending along the second direction; the orthographic projection of at least one second grid portion 202 on the base substrate 10 overlaps at least partially with the orthographic projection of the power line on the base substrate 10; and/or the orthotropic projections of at least one second grid portion 202 on the base substrate 10 overlaps at least partially with the orthotropic projection of the cathode lines on the base substrate 10.

For example, the power line and the cathode line are alternately arranged along the first direction.

For example, the electro-static discharge layer 20 includes a plurality of first grid portions 201 extending along the first direction and a plurality of second grid portions 202 extending along the second direction, where the first grid portion 201 is coupled to the second grid portion 202, defining the grid structure.

For example, the length of the second grid portion 202 is shorter than the length of the first grid portion 201, but is not limited to this.

In above arrangement, the orthotropic projection of at least one second grid portion 202 on the base substrate 10 overlaps at least partially with the orthotropic projection of the power line on the base substrate 10; and/or, the orthotropic projection of at least one second grid portion 202 on the base substrate 10 overlaps at least partially with the orthotropic projection of the cathode line on the base substrate 10; and it is conducive to achieving coupling between the electro-static discharge layer 20 and the power layer VDD or cathode layer VSS, which reducing the difficulty of coupling between the electro-static discharge layer 20 and the power layer VDD or the cathode layer VSS.

The electro-static discharge layer 20 is formed into a grid shape, which is conducive to gathering the static electricity generated in the process of manufacturing the display substrate and discharging the static electricity in time, which effectively preventing the ESD damage generated in the stages such as side, binding, and die bonding, playing the function of electro-static protection, and improving the product yield.

As shown in FIG. 13 to FIG. 16, in some embodiments, the display substrate includes a plurality of clock signal lines HF arranged along the second direction, the clock signal line HF includes at least a portion extending along the first direction, the pixel driving circuit is coupled to the corresponding clock signal line HF, and the orthotropic projection of the first grid portion 201 on the base substrate 10 overlaps at least partially with the orthotropic projection of the clock signal line HF on the base substrate 10.

For example, the display substrate further includes a plurality of data lines Data arranged along a second direction, where the data lines Data includes at least a portion extending along the first direction, and the pixel driving circuit is coupled to the corresponding data lines Data.

For example, the orthotropic projection of the first grid portion 201 on the base substrate 10 overlaps at least partially with the orthotropic projection of the clock signal line HF on the base substrate 10; and/or, the orthotropic projection of the first grid portion 201 on the base substrate 10 overlaps at least partially with the orthotropic projection of the data line Data on the substrate 10.

The above arrangement is conducive to improving the stability of the signals transmitted by the clock signal line HF and the data line Data.

As shown in FIG. 8 and FIG. 11, in some embodiments, the electro-static discharge layer 20 includes a plurality of first openings K1, the orthographic projection of the boundary of the first opening K1 on the base substrate 10 includes a curved edge portion, and the orthotropic projection of the first opening K1 on the base substrate 10 overlaps at least partially with the orthotropic projection of the pixel driving circuit on the base substrate 10.

For example, the curved edge portion forms a circle or an ellipse, but is not limited to this.

In the display substrate provided in the above embodiment, the orthotropic projection of the boundary of the first opening K1 on the base substrate 10 includes a curved edge portion, the first opening K1 can be formed into a circular or elliptical shape opening with a smooth boundary, where the opening is not easy to accumulate static electricity. Therefore, the orthotropic projection of the first opening K1 on the base substrate 10 overlaps at least partially with the orthotropic projection of the pixel driving circuit on the substrate 10, which can avoid accumulating static electricity in the region where the pixel driving circuit is arranged, causing the pixel driving circuit to directly release static electricity to the electro-static discharge layer 20, and affecting the stability of the pixel driving circuit, so that this arrangement ensures the yield of the pixel driving circuit.

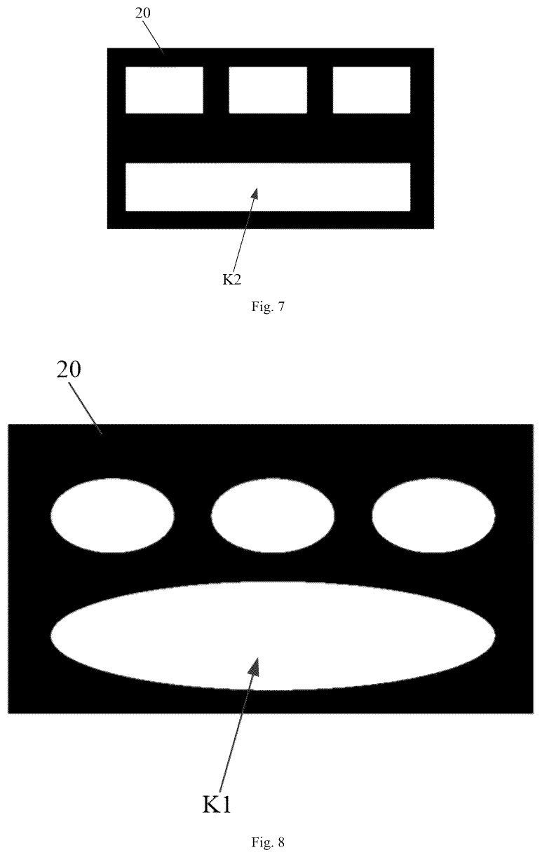

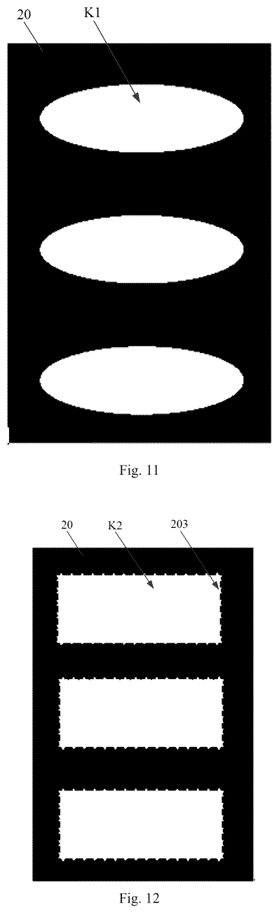

As shown in FIGS. 4, 7, 9, 10, and 12, in some embodiments, the electro-static discharge layer 20 includes a plurality of second openings K2, and the orthogonal projection of the boundary of the second opening K2 on the base substrate 10 includes a straight edge portion; and the orthogonal projection of the second opening K2 on the base substrate 10 does not overlap with the orthogonal projection of the pixel driving circuit on the base substrate 10.

For example, the orthogonal projection of the boundary of the second opening K2 on the base substrate 10 includes triangles, rectangles, or other polygons with straight edge portions, but is not limited to this.

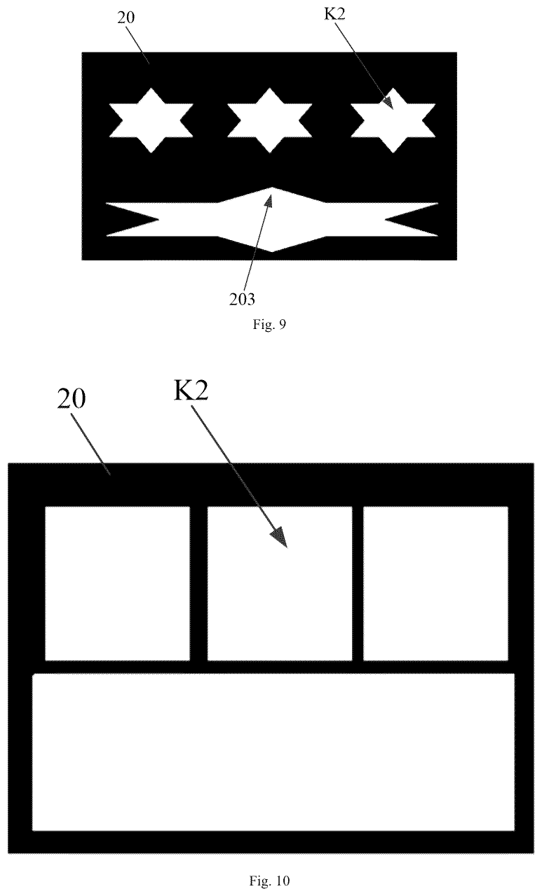

As shown in FIGS. 9 and 12, for example, the orthogonal projection of the boundary of the second opening K2 on the base substrate 10 includes at least one serrated portion 203, that is, the second opening K2 includes an opening with a serrated shape.

In the display substrate provided in the above embodiment, the orthographic projection of the boundary of the second opening K2 on the base substrate 10 includes a straight edge portion, so that the second opening K2 can be formed as an opening with sharp angles, and the opening is easy to accumulate static electricity. The orthotropic projection of the second opening K2 on the base substrate 10 does not overlap with the orthographic projection of the pixel driving circuit on the base substrate 10, and the orthotropic projection of the second opening K2 on the base substrate 10 overlaps at least partially with the orthographic projection of the peripheral region of the pixel driving circuit, so that the second opening K2 can attract static electricity in the surrounding region and discharge the static electricity to ensure the yield of the display substrate.

As shown in FIG. 13 to FIG. 18, in some embodiments, the pixel driving circuit includes a driving transistor (i.e., a third transistor M3) and a storage capacitor Cs, the first electrode plate Cs1 of the storage capacitor Cs is coupled to the gate of the driving transistor, and the second electrode plate Cs2 of the storage capacitor Cs is coupled to the power layer VDD; and
the orthographic projection of the second electrode plate Cs2 on the base substrate 10 and the orthographic projection of the electro-static discharge layer 20 on the base substrate 10 have an overlapping region, and the second electrode plate Cs2 is coupled to the electro-static discharge layer 20 through a via-hole Via-hole3 in the overlapping region. At the same time, the second electrode plate Cs2 is coupled to the power layer VDD through a via-hole Via-hole1, and the second electrode plate Cs2 is coupled to the light shielding layer LS through a via-hole Via-hole2.

For example, the second electrode plate Cs2 is arranged with the same layer and the same material as the source drain metal layer, but is not limited to this.

As shown in FIG. 17, for example, a first light shielding pattern (as marked LS) is provided between the second electrode plate Cs2 and the base substrate 10, an electro-static discharge layer 20 is provided between the first light shielding pattern and the base substrate 10, and the orthotropic projection of the second electrode plate Cs2 on the base substrate 10 has an overlapping region with the orthotropic projection of the electro-static discharge layer 20 on the base substrate 10. At least part of the first light shielding pattern is arranged in the overlapping region, the second electrode plate is coupled to the electro-static discharge layer 20 through a via-hole Via-hole3 in the overlapping region, and the via-hole Via-hole3 can penetrate the first light shielding pattern arranged in the overlapping region.

The above arrangement makes it possible not to change the layout of the pixel driver circuit and the light shielding layer LS, and only needs to manufacture the electro-static discharge layer 20 at a designated position, which is conducive to reducing the overall layout difficulty of the display substrate, simplifying the production process, and saving the production cost.

In some embodiments, the display substrate further includes a first conductive connection portion, the first conductive connection portion is coupled to the power line, and at least part of the first conductive connection portion is arranged on a side of the power line away from the base substrate 10; and
the orthotropic projection of the first conductive connection portion on the base substrate 10 has an overlapping region with the orthotropic projection of the electro-static discharge layer 20 on the base substrate 10, and the first conductive connection portion is coupled to the electro-static discharge layer 20 through a via-hole in the overlapping region.

For example, the first conductive connection portion is arranged with the same layer and the same material as the source drain metal layer, but is not limited to this. This arrangement is conducive to shortening the distance between the first conductive connection portion and the electro-static discharge layer 20, reducing the difficulty of manufacturing the via-holes used for connecting the first conductive connection portion and the electro-static discharge layer 20, and this arrangement is applicable to both large-size and small-size pixel driving circuits.

For example, the thickness of the electro-static discharge layer 20 and the size of the formed opening can be determined by the ability to prevent ESD and the upper and lower relationship with the source drain metal layer.

In the display substrate provided in the embodiment, the coupling between the electro-static discharge layer 20 and the power line is realized by arranging a first conductive connection portion, so that the position of the electro-static discharge layer 20 can be more flexibly arranged, which reducing the layout difficulty of the display substrate.

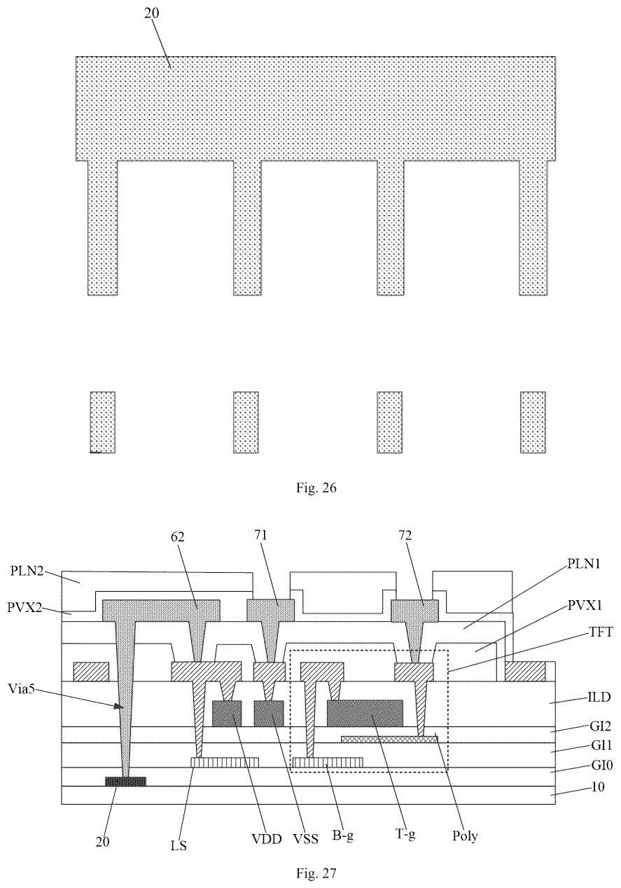

As shown in FIG. 25 to FIG. 28, in some embodiments, the display substrate further includes a first conductive connection portion and a second conductive connection portion 62, at least part of the second conductive connection portion 62 is arranged on a side of the first conductive connection portion away from the base substrate 10; the first conductive connection portion is coupled to the second conductive connection portion 62 and the power layer respectively; the orthotropic projection of the second conductive connection portion 62 on the base substrate 10 has an overlapping region with the orthographic projection of the electro-static discharge layer 20 on the base substrate 10, and the second conductive connection portion 62 is coupled to the electro-static discharge layer 20 through a via-hole Via-hole5 in the overlapping region.

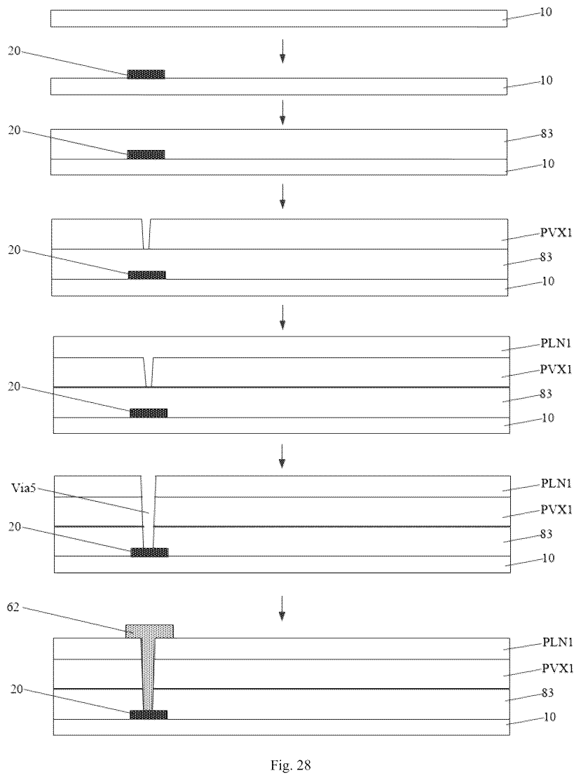

As shown in FIG. 28, for example, the second conductive connection portion 62 is arranged with the same layer and the same material as the conductive layer 50, but is not limited to this. In this arrangement, the second conductive connection portion 62 is far away from the electro-static discharge layer 20, the via-hole Via-hole5 used for connecting the second conductive connection portion 62 and the electro-static discharge layer 20 has a deep depth, and the via-hole Via-hole5 penetrates through the insulation layer 83 between the electro-static discharge layer 20 and the light shielding layer LS (including an insulation layer GI0, the first insulation layer GI1, the second insulation layer GI2 and the interlayer insulation layer ILD), the first passivation layer PVX1 and the first planarization layer PLN1.

In the display substrate provided in the above embodiment, the coupling between the electro-static discharge layer 20 and the power line is realized by arranging a second conductive connection portion 62, so that the position of the electro-static discharge layer 20 can be more flexibly arranged, which reducing the layout difficulty of the display substrate.

As shown in FIG. 23, in some embodiments, the display substrate further includes a third conductive connection portion 63, the third conductive connection portion 63 is coupled to the cathode layer VSS, and at least part of the third conductive connection portion 63 is arranged on a side of the cathode layer VSS away from the base substrate 10; and
the orthotropic projection of the third conductive connection portion 63 on the base substrate 10 have an overlapping region with the orthotropic projection of the electro-static discharge layer 20 on the base substrate 10, and the third conductive connection portion 63 is coupled to the electro-static discharge layer 20 through a via-hole Via-hole7 in the overlapping region.

For example, the third conductive connection portion 63 is arranged with the same layer and the same material as the source drain metal layer, but is not limited to this. This arrangement is conducive to shortening the distance between the third conductive connection portion 63 and the electro-static discharge layer 20, which reducing the difficulty of manufacturing a via-hole for connecting the third conductive connection portion 63 and the electro-static discharge layer 20, and this arrangement is applicable to both large-size and small-size pixel driving circuits.

In the display substrate provided in the above embodiment, the coupling between the electro-static discharge layer 20 and the cathode layer VSS is realized by arranging a third conductive connection portion 63, so that the position of the electro-static discharge layer 20 can be more flexibly arranged, which reducing the layout difficulty of the display substrate.

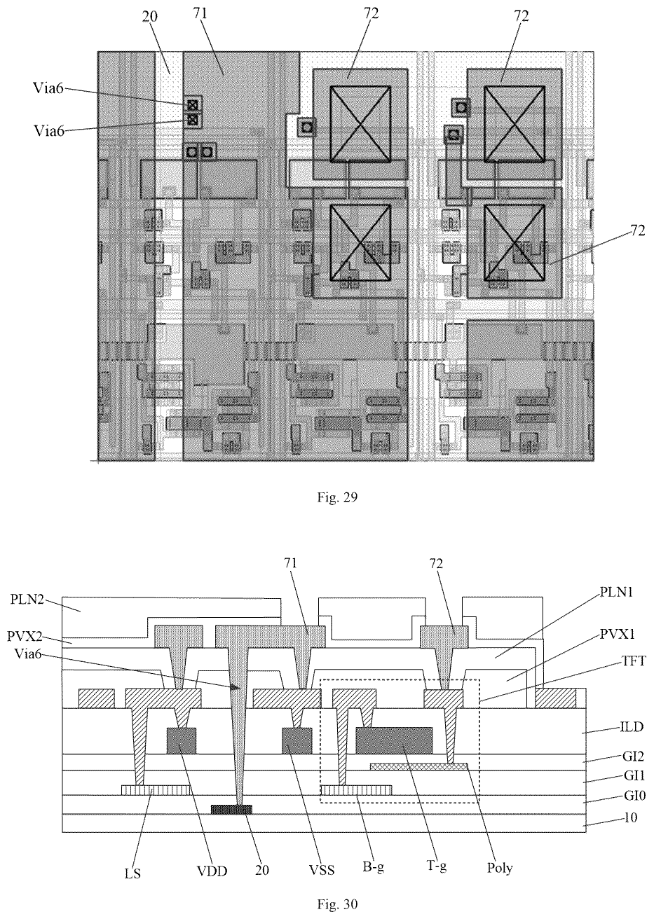

As shown in FIG. 29 and FIG. 30, in some embodiments, the display substrate further includes a first connection electrode 71 and a third conductive connection portion 63, at least part of the first connection electrode 71 is arranged on a side of the third conductive connection portion 63 away from the base substrate 10; the third conductive connection portion 63 is coupled to the first connection electrode 71 and the cathode layer VSS respectively; and the orthographic projection of the first connection electrode 71 on the base substrate 10 has an overlapping region with the orthographic projection of the electro-static discharge layer 20 on the base substrate 10, and the first connection electrode 71 is coupled to the electro-static discharge layer 20 through a via-hole Via-hole6 in the overlapping region.

For example, the first connection electrode 71 is arranged with the same layer and the same material as conductive layer 50, but is not limited to this. In this arrangement, the first connection electrode 71 is far away from the electro-static discharge layer 20, the via-hole used for connecting the first connection electrode 71 and the electro-static discharge layer 20 has a deep depth, and the via-hole penetrate through the insulation layer between the electro-static discharge layer 20 and the light shielding layer LS, the first insulation layer, the second insulation layer, the interlayer insulation layer, the first passivation layer and the first planarization layer.

In the display substrate provided in the embodiment, the coupling between the electro-static discharge layer 20 and the power line is realized by arranging the first connection electrode 71, so that the position of the electro-static discharge layer 20 can be more flexibly arranged, which reducing the layout difficulty of the display substrate.

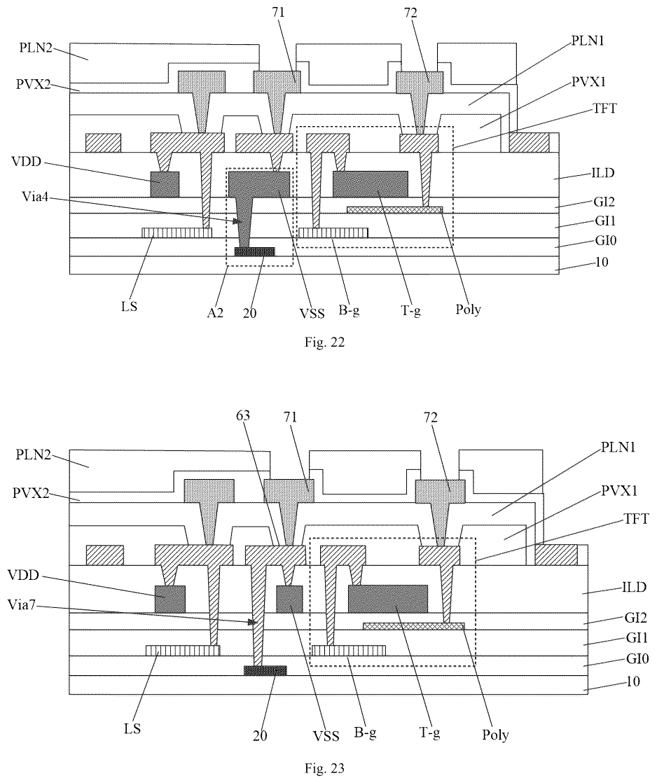

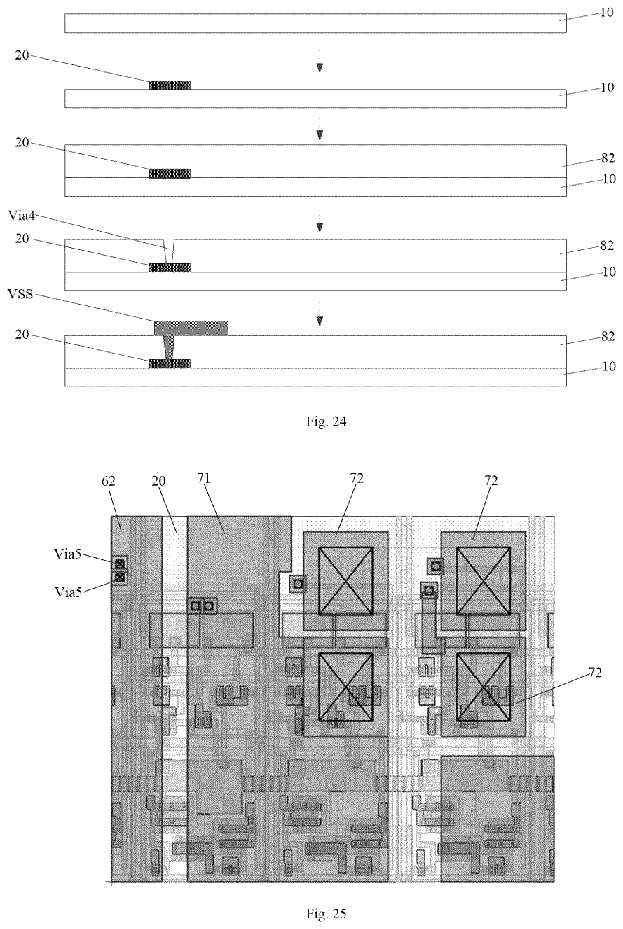

As shown in FIG. 19, FIG. 22 and FIG. 24, in some embodiments, the orthographic projection of the cathode layer VSS on the base substrate 10 has an overlapping region (such as part A2) with the orthographic projection of the electro-static discharge layer 20 on the base substrate 10, and the cathode layer VSS is coupled to the electro-static discharge layer 20 through a via-hole Via-hole4 in the overlapping region.

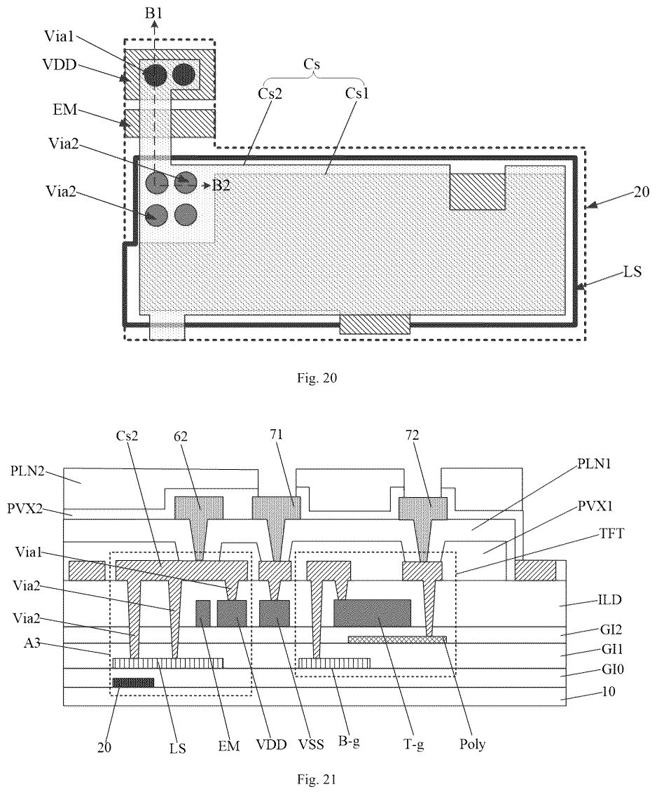

It should be noted that FIG. 20 is an enlarged schematic diagram of the same position as the part A1 of FIG. 13 in FIG. 19, and the conductive layer is not included in FIG. 20. In this embodiment, the cross-sectional schematic diagram along the B1B2 direction in FIG. 20 is shown in the part A3 of FIG. 21. It can be seen that in this embodiment, the second electrode plate Cs2 is not coupled to the electro-static discharge layer 20.

It is should be noted that the cross-sectional schematic diagram of part A2 in FIG. 19 can refer to part A2 in FIG. 22. The insulation layer 82 in FIG. 24 includes an insulation layer GI0, a first insulation layer GI1 and a second insulation layer GI2.

The above arrangement makes it possible not to change the layout of the pixel driving circuit and the light shielding layer LS, and only needs to manufacture the electro-static discharge layer 20 at a designated position, which is conducive to reducing the overall layout difficulty of the display substrate, simplifying the production process and saving the production cost.

As shown in FIG. 19 and FIG. 21, in some embodiments, the display substrate further includes a cathode layer VSS, a plurality of first connection electrodes 71, a plurality of second connection electrodes 72 and a plurality of light-emitting elements, where the first connection electrode 71 is coupled to the cathode layer VSS, the second connection electrode 72 is coupled to the corresponding pixel driving circuits, and the light-emitting element includes a first pin and at least one second pin, where the first pin is coupled to the corresponding first connection electrode 71, and the second pin is coupled to the corresponding second connection electrode 72.

For example, each light-emitting element includes three light-emitting units, and the three light-emitting units can be selected as red light-emitting units, green light-emitting units, and blue light-emitting units. The light-emitting element includes one first pin and three second pins, where the first pin is coupled to the cathode layer VSS, the three second pins correspond to the three light-emitting units one by one, and the second pin is coupled to the corresponding pixel driving circuit, receiving the driving signal provided by the pixel driving circuit. Each light-emitting unit can achieve independent control of light emission under the driving of the corresponding pixel driving circuit.

The specific structure of the pixel driving circuit is various, for example, such as 7T1C (i.e. 7 transistors and 1 capacitance), 8T1C (i.e. 8 transistors and 1 capacitance), 11T3C (i.e. 11 transistors and 3 capacitors) etc., and the following description takes the pixel driving circuit using 11T3C as an example.

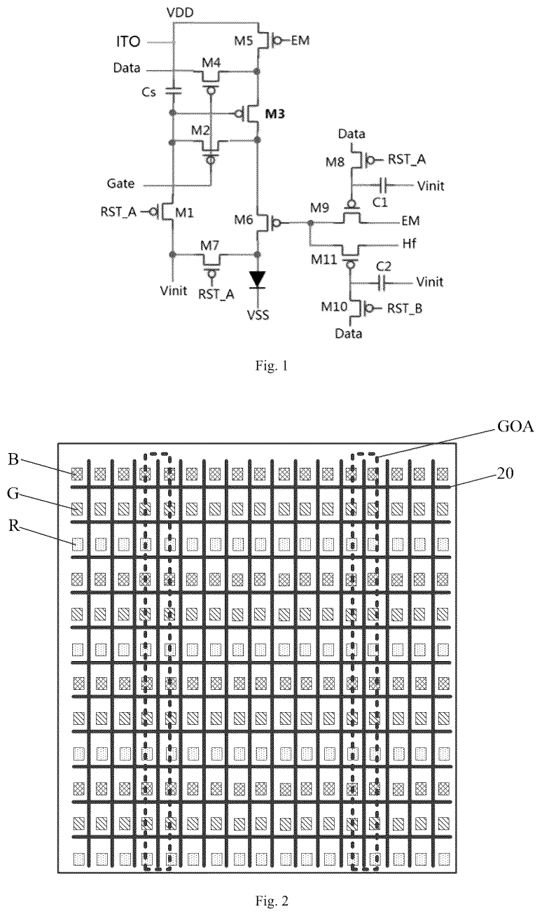

As shown in FIG. 1 and FIG. 14, the pixel drive circuit includes a first transistor M1, a second transistor M2, a third transistor M3, a fourth transistor M4, a fifth transistor M5, a sixth transistor M6, a seventh transistor, an eighth transistor M8, a ninth transistor M9, a tenth transistor M10, an eleventh transistor M11, a storage capacitor Cs, a first capacitor C1 and a second capacitor C2. The ITO shown in FIG. 1 represents that the electro-static discharge layer 20 is coupled to the power layer VDD.

The display substrate further include a plurality of light-emitting control signal lines EM, a plurality of scanning lines Gate, a plurality of data lines Data, a plurality of first reset signal lines RST_A, a plurality of second reset signal lines RST_B, a plurality of initialization signal lines Vinit and a plurality of clock signal lines HF.

The gate of the first transistor M1 is coupled to the corresponding first reset signal line RST_ARST_A, the first electrode of the first transistor M1 is coupled to the initialization signal line Vinit, and the second electrode of the first transistor M1 is coupled to the gate of the third transistor M3.

The gate of the second transistor M2 is coupled to the scanning line Gate, the first electrode of the second transistor M2 is coupled to the second electrode of the third transistor M3, and the second electrode of the second transistor M2 is coupled to the gate of the third transistor M3.

The gate of the fourth transistor M4 is coupled to the scanning line Gate, the first electrode of the fourth transistor M4 is coupled to the corresponding data line Data, and the second electrode of the fourth transistor M4 is coupled to the first electrode of the third transistor M3.

The gate of the fifth transistor M5 is coupled to the corresponding light-emitting control signal line EM, the first electrode of the fifth transistor M5 is coupled to the power line, and the second electrode of the fifth transistor M5 is coupled to the first electrode of the third transistor M3.

The first electrode of the sixth transistor M6 is coupled to the second electrode of the third transistor M3, and the second electrode of the sixth transistor M6 is coupled to the corresponding second pin.

The gate of the seventh transistor is coupled to the corresponding first reset signal line RST_A, the first electrode of the seventh transistor is coupled to the initialization signal line Vinit, and the second electrode of the seventh transistor is coupled to the corresponding second pin.

The gate of the eighth transistor M8 is coupled to the corresponding first reset signal line RST_A, the first electrode of the eighth transistor M8 is coupled to the corresponding data line Data, and the second electrode of the eighth transistor M8 is coupled to the gate of the ninth transistor M9.

The first electrode of the ninth transistor M9 is coupled to the corresponding light-emitting control signal line EM, and the second electrode of the ninth transistor M9 is coupled to the gate of the sixth transistor M6.

The gate of the tenth transistor M10 is coupled to the corresponding second reset signal line RST_B, the first electrode of the tenth transistor M10 is coupled to the corresponding data line Data, and the second electrode of the tenth transistor M10 is coupled to the gate of the eleventh transistor M11.

The first electrode of the eleventh transistor M11 is coupled to the corresponding clock signal line HF, and the second electrode of the eleventh transistor M11 is coupled to the gate of the sixth transistor M6.

The first capacitor C1 is coupled to the gate of the initialization signal line Vinit and the ninth transistor M9 respectively. The second capacitor C2 is coupled to the gate of the initialization signal line Vinit and the eleventh transistor M11 respectively.

For example, each of transistor in the pixel driving circuit includes a low-temperature polycrystalline silicon transistor. The display substrate includes a low-temperature polysilicon display substrate using COG (chip on glass) packaging technology, but is not limited to this.

The disclosure embodiment further provides a display device including a display substrate according to any one of claims 1 to 19.

It is to be noted that the display device may be: any product or component with a display function, such as a television, a display, a digital photo border, a mobile phone, a tablet computer, and the display device further includes a flexible circuit board, a printed circuit board and a back plate.

The display substrate provided in the above embodiment includes a first level signal input layer and an electro-static discharge layer, at least part of the electro-static discharge layer is arranged on a side of the pixel driving circuit facing the base substrate, and the electro-static discharge layer is coupled to the first level signal input layer. This arrangement makes the electro-static discharge layer have the same stable first level signal as the first level signal input layer, and the electro-static discharge layer can discharge the static electricity generated in the process of manufacturing the display substrate in time, which effectively preventing the ESD damage generated in the stages such as side, binding, and die bonding, playing the function of electro-static protection, and improving the product yield.

Moreover, in the display substrate provided in the above embodiment, the electro-static discharge layer is arranged on a side of the pixel driving circuit facing the base substrate. The arrangement is conducive to shortening the distance between the light-emitting element and the corresponding pixel driving circuit, which can effectively reduce the difficulty of manufacturing the display substrate. At the same time, the electro-static discharge layer can be manufactured in the Array process used for manufacturing display substrate, and there is no need to add a separate process to manufacture the electro-static discharge layer after completing the Array process. Therefore, the display substrate provided in the above embodiment has lower manufacturing difficulty and simple manufacturing process flow, and is conducive to reducing the production cost of the display substrate.

In addition, in the display substrate provided in the above embodiment, the electro-static discharge layer 20 is arranged on a side of the pixel driving circuit facing the base substrate 10, which can enhance the protective effect against the laser and reduce the damage to the transistors of pixel driving circuit on the front side when the display substrate is in backside laser etching.

The display device provided in the embodiment of the present disclosure also has the above-mentioned beneficial effect when including the display substrate, and will not be repeated here.

It is to be noted that the signal line extending in the X direction means that: the signal line includes a main part and a secondary part connected to the main part, the main part is a line, a line segment or a bar-shaped body, the main part extends in the X direction, and the length of the main part extends in the X direction is greater than the length of the secondary part extending in another direction.

It is to be noted that the “same layer” in the embodiments of the present disclosure may refer to film layers being on the same structural layer. Or, for example, the film layer in the same layer may be a layer structure formed by forming a film layer for forming a specific pattern using a single film forming process and then patterning the film layer by one patterning process using the same mask plate. Depending on the particular pattern, the single patterning process may include multiple exposure, development, or etching processes, and the particular pattern in the resulting layer structure may or may not be continuous. The particular patterns may also be at different heights or have different thicknesses.

In various method embodiments of the present disclosure, the serial number of each step cannot be used to define the order of each step, and a person of ordinary skill in the art can change the order of each step without involving inventive effort, which shall also fall within the protection scope of the present disclosure.

It should be noted that the various embodiments described herein are described in a progressive manner, the same or similar parts of the various embodiments can refer to each other, and each embodiment focuses on differences from the other embodiments. In particular, the method embodiments are described more simply because they are substantially similar to the product embodiments, and for the interrelated part, the partial description of the product embodiments may be referred to.

Unless defined otherwise, technical or scientific terms used in this disclosure shall have the ordinary meaning as understood by one of ordinary skill in the art to which this disclosure belongs. Such terms as “first”, “second” used herein do not denote any order, quantity, or importance, but rather are used to distinguish one element from another. Such terms as “comprise” or “include” mean that the presence of an element or item preceding the word covers the presence of the element or item listed after the word and equivalents thereof, but does not exclude other elements or items. Such terms as “connecting” or “connected” are not limited to physical or mechanical connections, but may include electrical connections, whether direct or indirect. The terms “upper”, “lower”, “left”, “right” and the like are used only to indicate relative positional relationships that may change accordingly when the absolute position of the object being described changes.

It will be understood that when an element such as a layer, film, region or substrate is referred to as being “on” or “under” another element, it can be “directly on” or “directly under” the other element or intervening elements may be present.

In the description of the above embodiments, particular features, structures, materials, or characteristics may be combined in any suitable manner in any one or more embodiments or examples.

The above implementations are just specific embodiments of the present disclosure, but the protection scope of the present disclosure is not limited thereto. A person of ordinary skill in the art can think of changes or equivalents within the technical scope of the present disclosure, which shall fall within the protection scope of the present disclosure. Therefore, the protection scope of the present disclosure shall be subjected to the claims.

1. A display substrate, comprising:
a base substrate;
a plurality of pixel driving circuits on the base substrate;
a first level signal input layer; and
an electro-static discharge layer;
wherein at least part of the electro-static discharge layer is at a side of the pixel driving circuits facing the base substrate, and the electro-static discharge layer is coupled to the first level signal input layer.

2. The display substrate according to claim 1, wherein the first level signal input layer comprises a power layer, and the electro-static discharge layer is coupled to the power layer.

3. The display substrate according to claim 1, wherein the first level signal input layer comprises a cathode layer, and the electro-static discharge layer is coupled to the cathode layer.

4. The display substrate according to claim 1, wherein the first level signal input layer comprises a light shielding layer; at least part of the light shielding layer is between the pixel driving circuit layer and the base substrate; and the pixel driving circuit comprises a plurality of transistors; the transistor comprises an active layer; an orthotropic projection of the light shielding layer onto the base substrate overlaps at least partially with an orthotropic projection of the active layer of at least part of the transistors onto the base substrate; and the electro-static discharge layer is coupled to the light shielding layer.

5. The display substrate according to claim 4, wherein at least part of the electro-static discharge layer is between the light shielding layer and the base substrate; and the electro-static discharge layer is coupled to the light shielding layer through a via-hole; or, the electro-static discharge layer is arranged with the light shielding layer on the same layer, and the electro-static discharge layer is directly overlapped with the light shielding layer.

6. The display substrate according to claim 4, wherein an overlapping area between the orthographic projection of the electro-static discharge layer onto the base substrate and the orthographic projection of the light shielding layer onto the base substrate, is less than or equal to 10% of an area of the electro-static discharge layer.

7. The display substrate according to claim 1, wherein the display substrate further comprises a light shielding layer; at least part of the light shielding layer is between the pixel driving circuit layers and the base substrate; and there is no overlapping between the orthotropic projection of the electro-static discharge layer onto the base substrate and the orthotropic projection of the light shielding layer onto the base substrate.

8. The display substrate according to claim 1, wherein the display substrate comprises a power layer and a cathode layer; the power layer comprises a plurality of power lines arranged along a first direction; the power line comprises at least a portion extending along a second direction, and the first direction intersects with the second direction; and the cathode layer comprises a plurality of cathode lines arranged along the first direction, and the cathode line comprises at least a portion extending along the second direction; and
the electro-static discharge layer is of a grid shape, and the electro-static discharge layer comprises a plurality of first grid portions extending along the first direction and a plurality of second grid portions extending along the second direction; an orthographic projection of at least one of the second grid portions onto the base substrate overlaps at least partially with an orthographic projection of the power line onto the base substrate; and/or, an orthogonal projection of at least one of the second grid portions onto the base substrate overlaps at least partially with an orthogonal projection of the cathode line onto the base substrate.

9. The display substrate according to claim 8, wherein the display substrate comprises a plurality of clock signal lines arranged along the second direction; the clock signal line comprises at least a portion extending along the first direction; and the pixel driving circuit is coupled to the corresponding clock signal line; and the orthographic projection of the first grid portion onto the substrate overlaps at least partially with the orthographic projection of the clock signal line onto the base substrate.

10. The display substrate according to claim 1, wherein the electro-static discharge layer comprises a plurality of first openings, and an orthogonal projection of a boundary of the first opening onto the base substrate comprises a curved edge portion; and an orthographic projection of the first opening onto the base substrate overlaps at least partially with the orthographic projection of the pixel driving circuit onto the base substrate.

11. The display substrate according to claim 1, wherein the electro-static discharge layer comprises a plurality of a second openings, and an orthogonal projection of a boundary of the second opening onto the base substrate comprises a straight edge portion; and there is no overlapping between an orthographic projection of the second opening onto the base substrate and the orthographic projection of the pixel driving circuit onto the base substrate.

12. The display substrate according to claim 11, wherein the orthogonal projection of the boundary of the second opening onto the base substrate comprises at least one serrated portion.

13. The display substrate according to claim 2, wherein the pixel driving circuit comprises a driving transistor and a storage capacitor; a first electrode plate of the storage capacitor is coupled to a gate of the driving transistor, and a second electrode plate of the storage capacitor is coupled to the power layer; and
an orthographic projection of the second electrode plate onto the base substrate has an overlapping region with the orthographic projection of the electro-static discharge layer onto the base substrate; and the second electrode plate is coupled to the electro-static discharge layer through a via-hole in the overlapping region.

14. The display substrate according to claim 2, wherein the display substrate further comprises a first conductive connection portion, the first conductive connection portion is coupled to the power line, and at least part of the first conductive connection portion is arranged on a side of the power line away from the base substrate; and
an orthographic projection of the first conductive connection portion onto the base substrate has an overlapping region with the orthographic projection of the electro-static discharge layer onto the base substrate, and the first conductive connection portion is coupled to the electro-static discharge layer through a via-hole.

15. The display substrate according to claim 2, wherein the display substrate further comprises a first conductive connection portion and a second conductive connection portion; at least part of the second conductive connection portion is arranged on a side of the first conductive connection portion away from the base substrate; the first conductive connection portion is coupled to the second conductive connection portion and the power layer, respectively;
and an orthographic projection of the second conductive connection portion onto the base substrate has an overlapping region with the orthographic projection of the electro-static discharge layer onto the base substrate; and the second conductive connection portion is coupled to the electro-static discharge layer through a via-hole in the overlapping region.

16. The display substrate according to claim 3, wherein the display substrate further comprises a third conductive connection portion; the third conductive connection portion is coupled to the cathode layer; and at least part of the third conductive connection portion is arranged on a side of the cathode layer away from the base substrate; and
an orthographic projection of the third conductive connection portion onto the base substrate has an overlapping region with the orthographic projection of the electro-static discharge layer onto the base substrate; and the third conductive connection portion is coupled to the electro-static discharge layer through a via-hole in the overlapping region.

17. The display substrate according to claim 3, wherein the display substrate further comprises a first connection electrode and a third conductive connection portion; at least part of the first connection electrode is arranged on a side of the third conductive connection portion away from the base substrate; the third conductive connection portion is coupled to the first connection electrode and the cathode layer, respectively; and an orthographic projection of the first connection electrode onto the substrate has an overlapping region with the orthographic projection of the electro-static discharge layer onto the base substrate; and the first connection electrode is coupled to the electro-static discharge layer through a via-hole in the overlapping region.

18. The display substrate according to claim 3, wherein an orthographic projection of the cathode layer onto the base substrate has an overlapping region with the orthographic projection of the electro-static discharge layer onto the base substrate, and the cathode layer is coupled to the electro-static discharge layer through a via-hole in the overlapping region.

19. The display substrate according to claim 1, wherein the electro-static discharge layer is made of an indium tin oxide material or an amorphous silicon.

20. A display device, comprising a display substrate;
a base substrate;
a plurality of pixel driving circuits on the base substrate;
a first level signal input layer; and
an electro-static discharge layer;
wherein at least part of the electro-static discharge layer is at a side of the pixel driving circuits facing the base substrate, and the electro-static discharge layer is coupled to the first level signal input layer.
